(19) United States
(12) Patent Application Publication
(10) Pub. No.: US 2012/0056298 A1
(43) Pub. Date: Mar. 8, 2012

(54) Semiconductor Device

(75) Inventor: Koji Kuroki, Tokyo (JP)

(73) Assignee: Elpida Memory, Inc., Tokyo (JP)

(21) Appl. No.: 13/137,484

(22) Filed: Aug. 19, 2011

(30) Foreign Application Priority Data
Aug. 25, 2010 (JP) 2010-188311

(51) Int. Cl. H01L 27/10

(52) U.S. Cl. 257/532; 257/E27.07

(57) ABSTRACT

A semiconductor device includes a first power supply terminal, a second power supply terminal, and first and second capacitors. The first power supply terminal is configured to be supplied with a first electrical potential. The second power supply terminal is configured to be supplied with a second electrical potential. The second electrical potential is different from the first electrical potential. The first and second capacitors are coupled in series between the first and second power supply terminals.

### BACKGROUND OF THE INVENTION

1. Field of the Invention

The present invention generally relates to a semiconductor device.

Priority is claimed on Japanese Patent Application No. 2010-188311, filed Aug. 25, 2010, the content of which is incorporated herein by reference.

2. Description of the Related Art

In general, in order to meet demands for reduced power consumption in semiconductor devices such as DRAMs, advances are being made in the reduction of the operating power supply voltage of the circuit elements. Specifically, the power supply voltage that is externally supplied is generally lowered to a desired voltage within the semiconductor device, and then is supplied to the circuit elements.

Because a reduction in the operating power supply voltage increases the influence of variation of power supply voltage on circuit operation, the supply of a stabilized power supply voltage has become important in recent years. Japanese Unexamined Patent Application, First Publication, No. JP-A-2010-67661 discloses that a compensation capacitor (capacitor) is disposed between the power supply voltage supplying wiring and the ground voltage supplying wiring.

Because such compensation capacitors are formed in the vertical cross-section direction, with respect to a semiconductor substrate, in the semiconductor device, they have the advantage of achieving a capacitance per unit surface area that is larger than another general transistor-type compensating capacitance.

Also, Japanese Unexamined Patent Application, First Publication, No. JP-A-H7-74309 discloses a semiconductor device including a capacitor that is formed by simply arranging a plurality of unit capacitors in series.

### SUMMARY

In one embodiment, a semiconductor device may include, but is not limited to, a first power supply terminal, a second power supply terminal, and first and second capacitors. The first power supply terminal is configured to be supplied with a first electrical potential. The second power supply terminal is configured to be supplied with a second electrical potential. The second electrical potential is different from the first electrical potential. The first and second capacitors are coupled in series between the first and second power supply terminals.

In another embodiment, a semiconductor device may include, but is not limited to, a shielding wiring, a connection wiring, a first power supply terminal, first and second capacitors, and a transistor. The connection wiring is adjacent to and separated from the shielding wiring. The first and second capacitors are coupled in series to the power supply terminal. The first and second capacitors are coupled via the connection wirings to each other. The transistor is coupled to one of the first and second capacitors. The shield wiring is disposed between the transistor and a combination of the first and second capacitors.

In still another embodiment, a semiconductor device may include, but is not limited to, a multilevel wiring structure, a first wiring layer, and a capacitive structure. The multilevel wiring structure includes first, second, and third levels of wiring. The second level of wiring is between the first and second levels of wiring. The first wiring layer is formed as one of the first and third levels of wiring. The first wiring layer is electrically fixed. The capacitive structure includes first and second capacitors connected in series. The first and second capacitors each include first and second electrodes, a second wiring layer, a third wiring layer, and a fourth wiring layer. The second wiring layer is formed as the second level of wiring to serve in common as the first electrodes of the first and second capacitors. The third wiring layer is formed as the other of the first and third levels of wiring layer to serve as the second electrode of the first capacitor. The fourth wiring layer is formed as the other of the first and third levels of wiring to serve as the second electrode of the second capacitor. The first wiring layer is provided adjacently to the second wiring layer.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic plan view illustrating a DRAM using a semiconductor device in accordance with one embodiment of the present invention;

FIG. 2 is a fragmentary schematic view illustrating a region G of the semiconductor device of FIG. 1 in accordance with one embodiment of the present invention;

FIG. 3 is a fragmentary cross sectional elevation view illustrating the semiconductor device in accordance with one embodiment of the present invention;

FIG. 4 is a fragmentary perspective view illustrating the semiconductor device in accordance with one embodiment of the present invention;

FIG. 5 is a circuit diagram of the semiconductor device in accordance with one embodiment of the present invention;

FIG. 6 is a fragmentary cross sectional elevation view illustrating the semiconductor device in a step involved in the method of forming the semiconductor device in accordance with one embodiment of the present invention;

FIG. 7 is a fragmentary cross sectional elevation view illustrating the semiconductor device in a step, subsequent to the step of FIG. 6, involved in the method of forming the semiconductor device in accordance with one embodiment of the present invention;

FIG. 8 is a fragmentary cross sectional elevation view illustrating the semiconductor device in a step, subsequent to the step of FIG. 7, involved in the method of forming the semiconductor device in accordance with one embodiment of the present invention;

FIG. 9 is a fragmentary cross sectional elevation view illustrating the semiconductor device in a step, subsequent to the step of FIG. 8, involved in the method of forming the semiconductor device in accordance with one embodiment of the present invention;

FIG. 10 is a fragmentary cross sectional elevation view illustrating the semiconductor device in a step, subsequent to the step of FIG. 9, involved in the method of forming the semiconductor device in accordance with one embodiment of the present invention;

FIG. 11 is a fragmentary cross sectional elevation view illustrating the semiconductor device in a step, subsequent to the step of FIG. 10, involved in the method of forming the semiconductor device in accordance with one embodiment of the present invention;

FIG. 12 is a fragmentary cross sectional elevation view illustrating the semiconductor device in a step, subsequent to the step of FIG. 11, involved in the method of forming the semiconductor device in accordance with one embodiment of the present invention;

FIG. 13 is a fragmentary cross sectional elevation view illustrating the semiconductor device in a step, subsequent to the step of FIG. 12, involved in the method of forming the semiconductor device in accordance with one embodiment of the present invention;

FIG. 14 is a fragmentary perspective view illustrating a semiconductor device in accordance with another embodiment of the present invention;

FIG. 15 is a fragmentary cross sectional elevation view illustrating a semiconductor device in accordance with still another embodiment of the present invention;

FIG. 16 is a fragmentary cross sectional elevation view illustrating a semiconductor device in accordance with yet another embodiment of the present invention; and

FIG. 17 is a circuit diagram of the semiconductor device in accordance with yet another embodiment of the present invention.

### DETAILED DESCRIPTION OF THE PREFERRED EMBODIMENTS

Before describing the present invention, the related art will be explained in order to facilitate the understanding of the present invention.

A compensation capacitor such as described in Japanese Unexamined Patent Application, First Publication, No. JP-A-2010-67661 is often formed by a process similar to that of a cell capacitor. In recent years, because of the demand for smaller sizes and achievement of cell capacitor capacitance, there is a trend for the capacitive insulating film to become thin, and the capacitive insulating films used in compensation capacitors have also become thin.

As a result, as described in Japanese Unexamined Patent Application, First Publication, No. JP-A-2010-67661, in the case in which one and the other end of the compensation capacitor are connected directly to a power supply, there is the problem of the capacitive insulating film not being able to withstand the voltage between the power supplies, and breaking down.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a semiconductor device may include, but is not limited to, a first power supply terminal, a second power supply terminal, and first and second capacitors. The first power supply terminal is configured to be supplied with a first electrical potential. The second power supply terminal is configured to be supplied with a second electrical potential. The second electrical potential is different from the first electrical potential. The first and second capacitors are coupled in series between the first and second power supply terminals.

In some cases, the semiconductor device may further include, but is not limited to, a connection wiring coupling the first and second capacitors.

In some cases, the semiconductor device may further include, but is not limited to, a shield wiring overlapping an entire region of the connection wiring.

In some cases, the semiconductor device may include, but is not limited to, the first capacitor including first and second electrodes and the second capacitor including third and fourth electrodes, the third electrode being coupled to the first electrode via the connection wiring.

In some cases, the semiconductor device may include, but is not limited to, the first and third electrodes being electrically floated.

In some cases, the semiconductor device may include, but is not limited to, the second electrode being configured to be supplied with the first electrical potential.

In some cases, the semiconductor device may further include, but is not limited to, a third capacitor coupled to the second capacitor in series, the third capacitor comprising fifth and sixth electrodes, the fifth electrode being coupled to the fourth electrodes.

In some cases, the semiconductor device may include, but is not limited to, the fourth and fifth electrodes are electrically floated.

In some cases, the semiconductor device may include, but is not limited to, the second power supply line overlapping the entire regions of the fourth and fifth electrodes.

In some cases, the semiconductor device may further include, but is not limited to, a transistor coupled to the first and second capacitors, the shielding wiring overlapping the transistor.

In another embodiment, a semiconductor device may include, but is not limited to, a shielding wiring, a connection wiring, a first power supply terminal, first and second capacitors, and a transistor. The connection wiring is adjacent to and separated from the shielding wiring. The first and second capacitors are coupled in series to the power supply terminal. The first and second capacitors are coupled via the connection wirings to each other. The transistor is coupled to one of the first and second capacitors. The shield wiring is disposed between the transistor and a combination of the first and second capacitors.

In some cases, the semiconductor device may include, but is not limited to, the shield wiring being supplied with substantially the same potential as the first power supply terminal.

In some cases, the semiconductor device may include, but is not limited to, the connection wiring being supplied with substantially the same potential as the first power supply terminal.

In some cases, the semiconductor device may include, but is not limited to, the connection wiring being disposed over the shielding wiring.

In some cases, the semiconductor device may further include, but is not limited to, a second power supply terminal. The first and second capacitors are coupled in series between the first and second power supply terminals.

In still another embodiment, a semiconductor device may include, but is not limited to, a multilevel wiring structure, a first wiring layer, and a capacitive structure. The multilevel wiring structure includes first (wirings 28 and 5 are provided), second (wirings 22a, 22b, and 22c are provided), and third levels (wirings 4a, 4b, and 4c are provided) of wiring. The second level of wiring is between the first and second levels of wiring. The first wiring layer is formed as one of the first and third levels of wiring. The first wiring layer is electrically fixed (the wiring 5 is fixed in VSS potential). The capacitive structure includes first and second capacitors (the capacitor defined by wall surfaces 48a and 49a and the capacitor defined by wall surfaces 48b and 49b) connected in series. The first and second capacitors each include first and second electrodes, a second wiring layer, a third wiring layer, and a fourth wiring layer. The second wiring layer is formed as the second level of wiring to serve in common as the first electrodes of the first and second capacitors (the wiring includes 22a and 22b). The third wiring layer is formed as the other of the first and third levels of wiring layer to serve as the second electrode of the first capacitor (the wiring includes 4a). The fourth wiring layer is formed as the other of the first and third levels of wiring to serve as the second electrode of the second capacitor (the wiring includes 4b). The first wiring layer is provided adjacently to the second wiring layer (the wiring 5 is provided adjacently to the wirings 22a and 22b).

In some cases, the capacitive structure may further include, but is not limited to, a third capacitor (the capacitor defined by wall surfaces 48c and 49c) and a fifth wiring layer. The third capacitor which includes first and second electrodes is connected in series to the first and second capacitors. The fifth wiring layer is formed as the second level of wiring (a wiring 22c) to serve as the first electrode of the third capacitor. The fourth wiring layer further serves as the second electrode of the third capacitor.

In some cases, the semiconductor device may include, but is not limited to, the third wiring layer being electrically fixed (the wiring 4a is fixed to VOD) and the second wiring layer being electrically floated (the wirings 22a and 22b).

In some cases, the semiconductor device may include, but is not limited to, the multilevel wiring structure further including a fourth level of wiring adjacent to the third level of wiring (wirings 29 and 23 are provided). The semiconductor device may include, but is not limited to, a sixth wiring layer as the fourth level of wiring (the wiring 23). The sixth wiring layer is electrically fixed (the wiring 23 is fixed in VSS). The sixth wiring layer is provided adjacently to the fourth wiring layer.

In some cases, the semiconductor device may include, but is not limited to, the third and fifth wiring layers being electrically fixed and the second and fourth wiring layers being electrically floated.

In yet another embodiment, a semiconductor device may include, but is not limited to, a first power supply terminal, a second power supply terminal, a plurality of capacitors, a plurality of connection wirings, and a shield wiring. The first power supply terminal is configured to be supplied with a first fixed potential. The second power supply terminal is configured to be supplied with a second fixed potential. The second electrical potential is different from the first fixed potential. The plurality of capacitors are coupled in series to each other between the first and second power supply terminals. The plurality of capacitors includes first and second capacitors and a sub-plurality of capacitors. The first capacitor includes a first electrode coupled to the first power supply terminal. The second capacitor includes a second electrode coupled to the second power supply terminal. Each capacitor of the sub-plurality of capacitors includes third and fourth electrodes. The third and fourth electrodes are electrically floated. Each of the plurality of connection wirings connects at least two of fourth electrodes. The shield wiring is adjacent to and separated from at least one of the connection wirings.

In some cases, the semiconductor device may include, but is not limited to, the shield wiring being configured to be supplied with the first fixed potential.

In some cases, the semiconductor device may include, but is not limited to, the first power supply terminal overlapping at least one third electrodes.

In some cases, the semiconductor device may further include, but is not limited to, a transistor coupled to the plurality of capacitors, the shielding wiring overlapping the transistor.

In some cases, the semiconductor device may include, but is not limited to, the shield wiring overlapping the connection wirings.

Hereinafter, a semiconductor device according to an embodiment of the invention will be described in detail with reference to the drawings. In the embodiment, an example of applying the invention to a DRAM (Dynamic Random Access Memory) as the semiconductor device will be described. In the drawings used for the following description, to easily understand characteristics, there is a case where characteristic parts are enlarged and shown for convenience' sake, and ratios of constituent elements may not be the same as in reality. Materials, sizes, and the like exemplified in the following description are just examples. The invention is not limited thereto and may be appropriately modified within a scope which does not deviate from the concept of the invention.

### FIRST EMBODIMENT

### <DRAM>

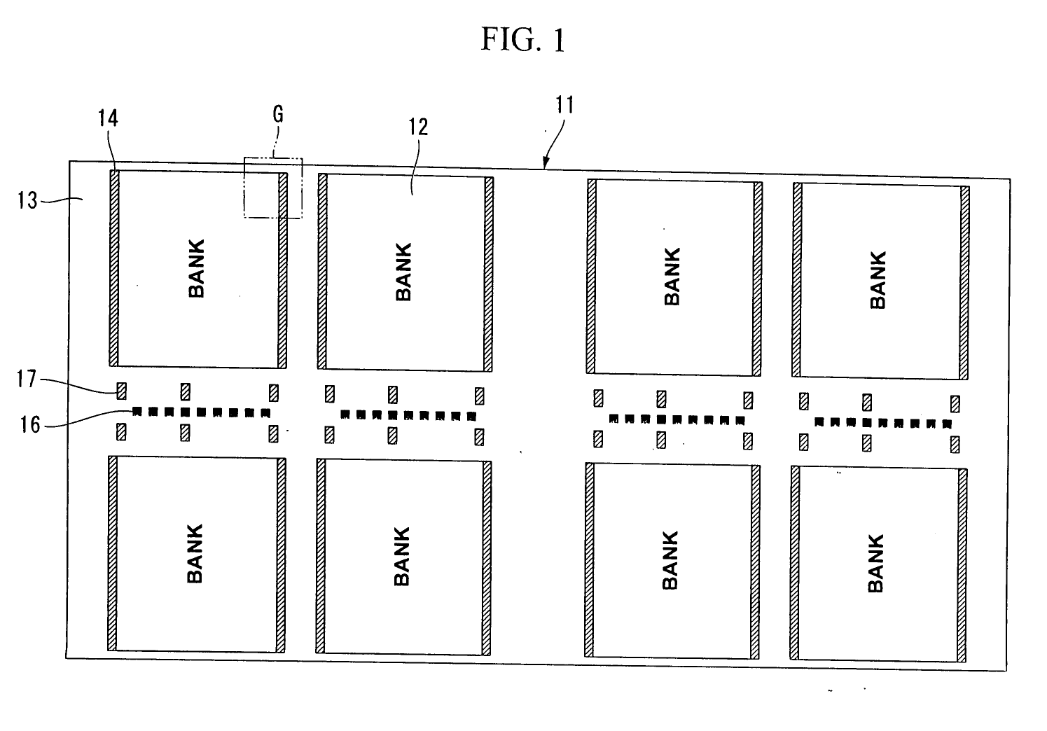

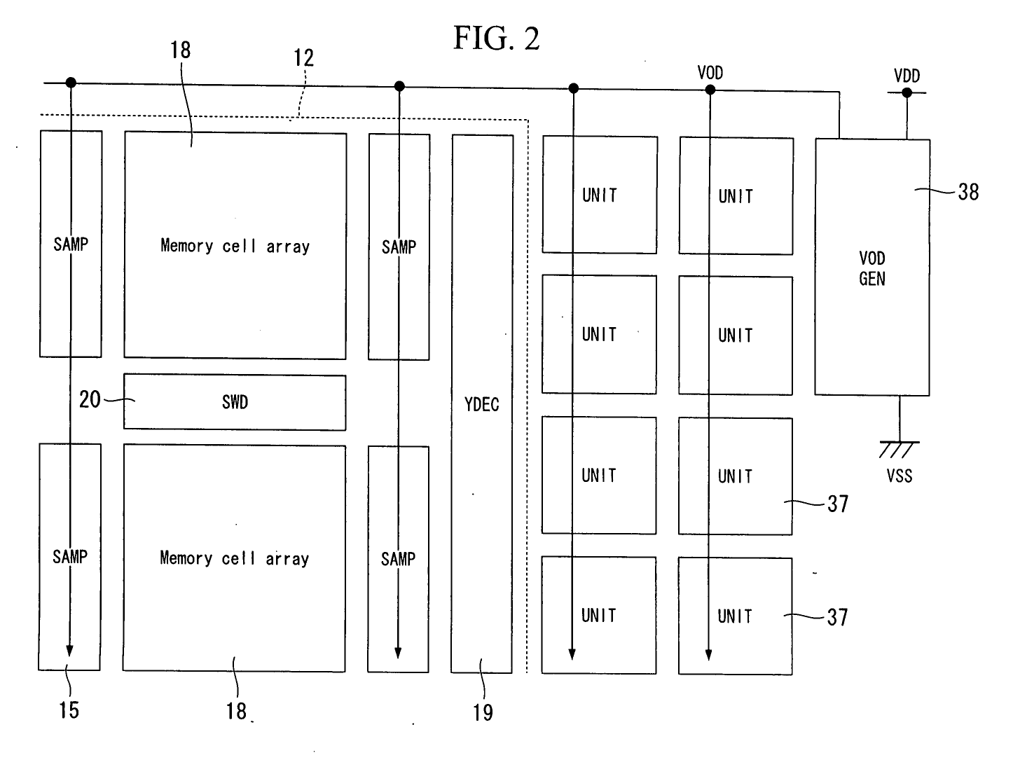

First, referring to FIGS. 1 and 2, a DRAM formed using a semiconductor device 1 of the present embodiment will be described. FIG. 1 is a schematic plan view illustrating a DRAM using a semiconductor device in accordance with one embodiment of the present invention. FIG. 2 is a fragmentary schematic view illustrating a region G of the semiconductor device of FIG. 1 in accordance with one embodiment of the present invention. The present embodiment is not restricted to a DRAM, and can be applied to any semiconductor device using a power supply, such as another type of memory (SRAM, flash, ReRAM, and PRAM) or a controller.

A semiconductor chip 11, as shown in FIG. 1, may include, but is not limited to, banks 12 and various devices and circuits formed in a peripheral region 13 outside of the banks 12. Although in FIG. 1 there are eight banks 12, the number of banks is not limited to eight, and may be, for example, four or sixteen or the like.

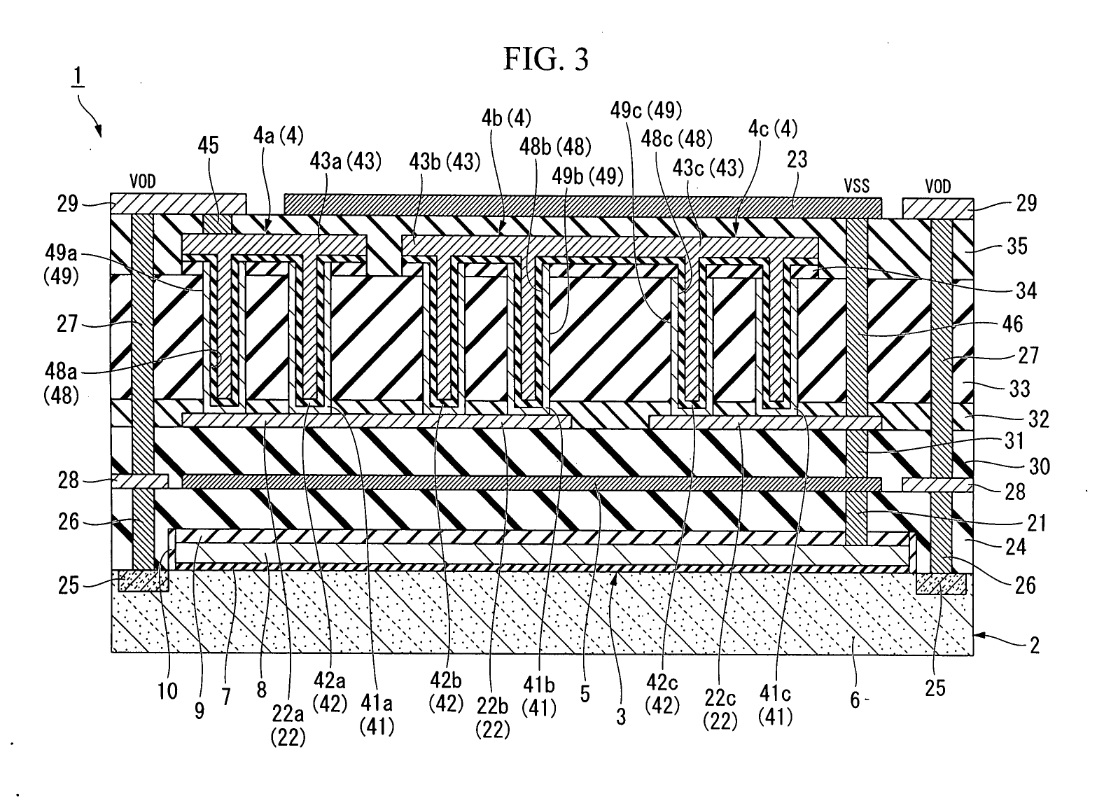

A region 14 is formed along each of two opposing sides of each bank 12. A plurality of compensation capacitors 4 (refer to FIG. 3) are disposed in the region 14. By providing the compensation capacitors 4 along the sides of the bank 12 in this manner, more effective power supply compensation is achieved. That is, the internal power supply voltage VOD is used in the sense amplifier (SAMP) 15 provided within the bank 12 (refer to FIG. 2). Therefore, power supply compensation is more effective by providing the compensation capacitors 4 near the locations at which the internal power supply voltage VOD is actually consumed.

A compensation capacitor 17 for a power supply such as an internal power supply VPERI that is generally used for peripheral circuits is disposed in the area surrounding a bonding pad 16 disposed in the center of the semiconductor chip 11. The internal power supply VPERI is different from the internal power supply. The compensation capacitor 17 may be formed with a structure that is similar to that of the compensation capacitor 4. The compensation capacitors 4 and 17 having similar structures may be disposed within one semiconductor chip 11 as compensating capacitances for differing power supplies.

As shown in FIG. 2, the bank 12 has a plurality of memory cell arrays 18. Each memory cell array 18 is provided with a bit line (omitted from the drawing) and a word line (omitted from the drawing), a transistor (omitted from the drawing) and a capacitor (cell capacitor) (omitted from the drawing) that is provided in a vicinity of the point of intersection between the bit line and the word line.

In FIG. 2, the compensation capacitor 4 is schematically shown as unit 37.

The word line is selected in response to an address signal input to an X decoder (omitted from the drawing). The bit line is selected in response to an address signal input to a Y decoder (YDEC) 19.

Within the bank 12, corresponding to each memory cell array 18, a subword driver (SWD) 20 that outputs to the word line, and a sense amplifier 15 that amplifies the electrical potential on the bit line are provided.

The unit 37 that corresponds to the compensation capacitors 4 along one side of the bank 12 is preferably disposed between the internal power supply voltage VOD generating circuit (VODGEN) 38 and the sense amplifier 15, which is the load circuit that operates by the internal power supply voltage VOD. By doing this, before the voltage consumed by (voltage drop across) the sense amplifier 15 is compensated by the generating circuit 38, it is compensated by the compensation capacitor 4.

Also, the generating circuit 38 receives the external power supply voltage VDD and ground voltage VSS and generates the internal power supply voltage VOD.

### <Semiconductor Device>

The semiconductor device 1 of the present embodiment will be described. The semiconductor device 1, as shown in FIG. 3, may include, but is not limited to, a transistor 3 formed on a semiconductor substrate 2, a plurality of compensation capacitors 4 (4a, 4b, and 4c) above the transistor 3 and a shield wiring 5.

FIG. 3 is a fragmentary cross sectional elevation view illustrating the semiconductor device in accordance with one embodiment of the present invention.

<<Transistor>>

The transistor 3 may include, but is not limited to, source and drain regions (source and drain terminals) 25 positioned in a well region 6 of the semiconductor substrate 2, a gate insulating film 7 on the semiconductor substrate 2, and a gate electrode 8 on the gate insulating film 7.

The semiconductor substrate 2 is, for example, p-type silicon, with an n-type well region 6 formed in the semiconductor substrate 2.

The gate insulating film 7 is provided on the semiconductor substrate 2. The gate electrode 8 is disposed over the gate insulating film 7. A protective insulating film 9 is provided over the gate electrode 8. A side wall 10 is positioned on the side wall of the gate electrode 8. The gate electrode 8 is electrically connected to the shield wiring 5, a connection wiring 22c, and a second power supply terminal 23, via the contact plugs 21, 31, and 46.

A gate interlayer insulating film 24 is disposed over the semiconductor substrate 2 so as to cover the gate electrode 8.

The source and drain regions 25 are self-aligned with respect to the gate electrode 8 in the well region 6 of the semiconductor substrate 2. The source and drain regions 25 are impurity diffusion regions in which, for example, a p-type impurity has been introduced. Boron (B) or the like is an example of the p-type impurity.

The source and drain regions 25 are connected to various wirings 28 and to the first power supply terminal 29, via the contact plugs 26 and 27.

In the present embodiment, a planar MOS transistor is explained as the transistor 3, but is not limited thereto. For example, a MOS transistor having a thin gate electrode or a vertical MOS transistor may be applicable. Also, a p-type transistor is explained as the transistor 3, but is not limited thereto. An n-type transistor may be used as the transistor 3. The configuration may be one in which the source and drain regions 25 are not p-type, but rather is made n-type, so that it shorts with the n-type well 6.

### <<Compensation Capacitor>>

Above the gate interlayer insulating film 24 is a first wiring layer. Various wirings 28 and the Shield wiring 5 are provided in the first wiring layer. The wirings 28 are provided so as to be electrically connected to the contact plugs 26. The shield wiring 5 is provided so as to be electrically connected to a contact plug 21.

The contact plugs 26 penetrate the gate interlayer insulating film 24 to be electrically connected to the source and drain regions 25, respectively. The contact plug 21 penetrates the gate interlayer insulating film 24 and protective insulating film 9 to be electrically connected to the gate electrode 8.

An interlayer insulating film 30 is provided on the gate interlayer insulating film 24 so as to cover the wiring 28 and the shield wiring 5. A contact plug 31 is provided on the shield wiring 5 so as to penetrate the interlayer insulating film 30 and be electrically connected to the shield wiring 5.

A second wiring layer is provided on the interlayer insulating film 30. A plurality of connection wirings (terminals) 22 (22a, 22b, and 22c) are provided in the second wiring layer. A stopper film 32 is provided so as to cover the connection wirings 22 (22a, 22b, and 22c). The connection wiring 22c is provided on the contact plug 31.

An interlayer insulating film 33 is provided on the stopper film 32. A support film 34 is provided in a region in which an upper electrode (second electrode) 43 (43a, 43b, and 43c) to be described below is provided. A plurality of compensation capacitors 4 are provided so as to penetrate the stopper film 32, the interlayer insulating film 33, and the support film 34. A third wiring layer is provided above the support film 34, via a capacitive insulating film 42. The third wiring layer partially functions as the upper electrode 43.

Each of the compensation capacitors 4 is formed above the transistor 3. Each of the compensation capacitors 4 has substantially the same type of shape as the capacitors formed in the memory cell array 18 (refer to FIG. 2). The compensation capacitors 4 may be formed by the same processes as the capacitors.

Each of the compensation capacitors 4 has a plurality of lower electrodes (first electrodes) 41 (41a, 41b, and 41c), capacitive insulating films 42 (42a, 42b, and 42c), and an upper electrode 43. The plurality of lower electrodes (first electrodes) 41 (41a, 41b, and 41c) are substantially the same constitution. The capacitive insulating films 42 (42a, 42b, and 42c) cover as one the plurality of lower electrodes 41. The upper electrodes 43 are provided over the capacitive insulating film 42. The lower electrodes 41 and the upper electrodes 43 are formed so as to sandwich the capacitive insulating films 42.

Each of the lower electrodes 41 is formed as a bottomed cylinder. The inner wall surface 48 (48a, 48b, and 48c) of the lower electrode 41 is covered by the capacitive insulating film 42. The outer wall surface 49 (49a, 49b, and 49c) of the lower electrode 41 is covered by the stopper film 32, the interlayer insulating film 33, and the support film 34.

The plurality of lower electrodes 41 in a compensation capacitor 4 are electrically connected by the connection wiring 22. For example, the plurality of lower electrodes 41a of the compensation capacitor 4a are all formed on one connection wiring 22a.

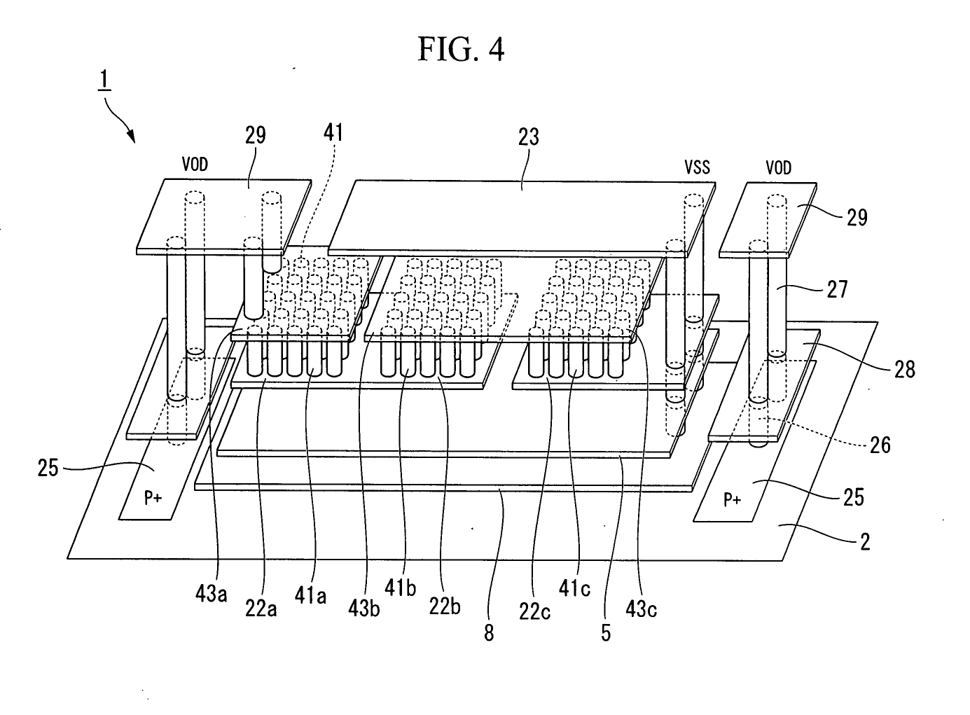

The lower electrodes 41 forming each of the compensation capacitors 4 are shown as two in FIG. 3, but are not limited thereto. The number of lower electrodes 41 forming each compensation capacitor 4 may be determined as appropriate to achieve a desired capacitance. Because when a plurality are formed the lower electrode 41 formed on the outermost periphery intrinsically has a low reliability, it is preferable that, rather than 2 rows by 2 columns of (that is, four), a greater number be formed, such as shown in FIG. 4. In FIG. 4, the semiconductor device 1 of the present embodiment is shown by an oblique view with a part thereof omitted.

The capacitive insulating film 42, as shown in FIG. 3, covers as one the inner wall surface 48 of the plurality of lower electrodes 41, so that there is no filling within the lower electrodes 41. An upper electrode 43 is provided over the capacitive insulating film 42. The upper electrode 43 fills the inside of the lower electrode 41 while the capacitive insulating film 42 is interposed between the upper electrode 43 and the lower electrode 41. The upper electrode 43 is shaped to couple the cylindrically shaped lower electrode 41.

The upper electrode 43, in the same manner as the capacitive insulating film 42, is formed so as to cover as one the plurality of lower electrodes 41 of the compensation capacitor 4 while the intervening capacitive insulating film 42 is interposed between the upper electrode 43 and the lower electrodes 41.

The capacitive insulating film 42a covers as one the inner wall surface 48a of the plurality of lower electrodes 41a of the compensation capacitor 4a. The upper electrode 43a fills the inside of the plurality of lower electrodes 41a while the capacitive insulating film 42a is interposed between the upper electrode 43a and the lower electrodes 41a.

In this manner, the compensation capacitor 4 of the present embodiment has a configuration that uses a plurality of so-called concave capacitive elements having an electrode structure that uses only the inner wall surface 48 of the lower electrode 41 formed as a cup shape as the capacitor electrode.

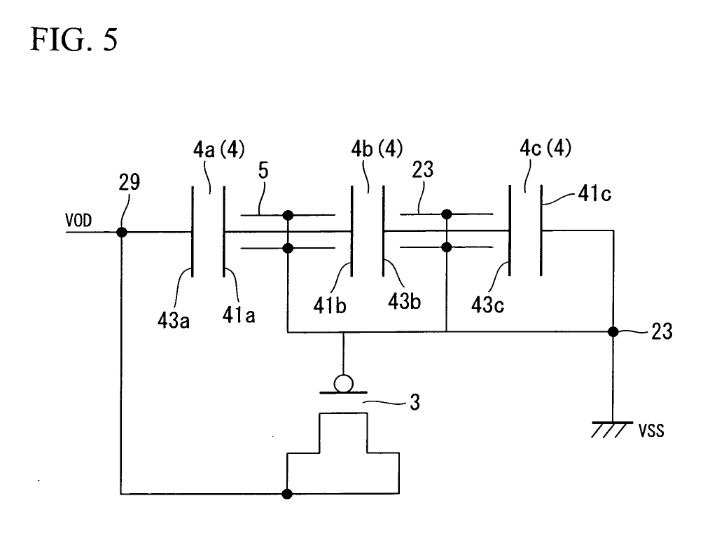

Also, as shown in the circuit diagram of FIG. 5, a plurality of compensation capacitors 4 (three in FIG. 5) are connected in series, between the first power supply terminal 29 which is supplied with the internal power supply voltage VOD (first voltage) and the second power supply terminal 23 which is supplied with the ground voltage VSS (second voltage).

As a description of a specific structure, as shown in FIG. 3, an interlayer insulating film 35 covers the upper electrode 43, the capacitive insulating film 42, and the interlayer insulating film 34. A fourth wiring layer is provided over the interlayer insulating film 35. The first power supply terminal 29, to which the internal power supply voltage VOD is supplied, and the second power supply terminal 23, to which the ground voltage VSS is supplied, are provided in the fourth wiring layer.

The first power supply terminal 29 and the upper electrode 43a of one of the compensation capacitors 4a of the plurality of compensation capacitors 4 are electrically connected via a contact plug 45.

The second power supply terminal 23 and the lower electrode 41c of the compensation capacitor 4c, which is other than the compensation capacitor to which the first power supply terminal 29 is connected, are electrically connected via the connection wiring 22c and a contact plug 46.

The connection wiring 22a provided under the lower electrode 41a of the compensation capacitor 4a and the connection wiring 22b provided under the lower electrode 41b of the compensation capacitor 4b disposed adjacent to the compensation capacitor 4a are formed as one and are electrically connected. That is, the connection wiring 22a and the connection wiring 22b are united as one and function as a capacitive coupling wiring that connects the compensation capacitor 4a and the compensation capacitor 4b in series.

The upper electrode 43b of the compensation capacitor 4b and the upper electrode 43c of the compensation capacitor 4c are also formed as one and are electrically connected. That is, the upper electrode 43b and the upper electrode 43c are united as one and function as a capacitive coupling wiring that connects the compensation capacitor 4b and the compensation capacitor 4c in series.

In this manner, in the compensation capacitor 4b, which is not directly connected to either the first power supply terminal 29 or the second power supply terminal 23, the lower electrode 41b is electrically connected to the lower electrode 41a of the adjacent compensation capacitor 4a. In the compensation capacitor 4b, the upper electrode 43b is electrically connected to the upper electrode 43 of an adjacent compensation capacitor 4c, different from the compensation capacitor 4a.

The plurality of compensation capacitors 4 are provided in series between the first power supply terminal 29 and the second power supply terminal 23. From the first power supply terminal 29, the first compensation capacitor 4a and the next, second compensation capacitor 4b are electrically connected by the connection wirings 22a and 22b. Also, the second compensation capacitor 4b and the next, third compensation capacitor 4c are electrically connected by the upper electrodes 43b and 43c.

In this manner, as shown in the circuit diagram of FIG. 5, a plurality of compensation capacitors 4 are connected in series between the first power supply terminal 29 and the second power supply terminal 23.

### <<Shield Wiring>>

As shown in FIG. 3, the shield wiring 5 that shields the lower electrode 41 from noise and the like is provided on the lower side (semiconductor substrate side) of the lower electrode 41. Specifically, it is preferred that the shield wiring 5 is provided over the gate interlayer insulating film 24 and over substantially the entire region in which the compensation capacitor 4 is provided. The shield wiring 5 covers (overlaps with) at least a region that is the projection of the connection wirings 22a and 22b, which function as capacitive coupling wirings, onto the gate interlayer insulating film 24.

The shield wiring 5 is electrically connected to the second power supply terminal 23 via the contact plugs 31 and 46 and the connection wiring 22c, and is supplied with the ground voltage VSS. In the present embodiment, the shield wiring 5 is supplied with the ground voltage VSS, but is not limited thereto. The shield wiring 5 may be configured to be supplied a fixed potential other than the ground voltage VSS.

That is, the shield wiring 5 is provided so as to be adjacent to the connection wirings 22a and 22b, which function as capacitive coupling wirings. The shield wiring 5 is supplied with a voltage that is substantially fixed. The term “adjacent” as used herein means provided adjacently while the insulating film is interposed between the shield wiring and the connection wirings. In this case, “the shield wiring 5 is provided adjacent to the connection wirings 22a and 22b” means “the shield wiring 5 is provided adjacently while the insulating film 30 is interposed between the shield wiring 5 and the connection wirings 22a and 22b.

In the present embodiment, the second power supply terminal 23 provided over the interlayer insulating film 35 shields the upper electrode 43 from noise and the like. That is, the second power supply terminal 23 provided above (on the side opposite from the semiconductor substrate of) the adjacent upper electrode 43 functions as a shield wiring.

It is therefore preferred that, over the interlayer insulating film 35, the second power supply terminal 23 is provided over substantially the entire region in which the compensation capacitor 4 is provided. The second power supply terminal 23 is provided on the interlayer insulating film 35 to cover (overlap with) at least a region of the upper electrodes 43b and 43c which function as capacitive coupling wirings.

According to the present embodiment, the compensation capacitor 4 is provided between the first power supply terminal 29, to which the internal power supply voltage VOD is supplied, and the second power supply terminal 23, to which the ground voltage VSS is supplied. By doing this, it is possible to suppress fluctuation of the internal power supply voltage VOD with a decrease in the operating power supply voltage, and to supply a stable internal power supply voltage VOD.

In addition to an electrical connection between the first power supply terminals 29 and the source and drain regions 25 of the transistor 3, there is an electrical connection between the second power supply terminal 23 and the gate electrode 8 of the transistor 3. Therefore, the transistor 3 functions as a capacitive element. Because of this, in addition to being able to supply a stable internal power supply voltage VOD, it is possible to achieve effective use of surface area. From the standpoint of effective use of surface area, rather than forming a transistor-type capacitive element, other functional elements (functional circuits) may be disposed in the region in which the transistor 3 is formed.

Also, the semiconductor device 1 includes the plurality of compensation capacitors 4 connected in series between the first power supply terminal 29, to which the internal power supply voltage VOD is supplied, and the second power supply terminal 23, to which the ground voltage VSS is supplied. By doing this, it is possible to prevent the destruction of the capacitive insulating film 42 of each of the compensation capacitors 4.

That is, in a semiconductor device in the related art, each compensation capacitor had an internal power supply voltage (or ground voltage) applied to the upper electrode, and a ground voltage (or internal power supply voltage) applied to the lower electrode. Therefore, there are cases in which the capacitive insulating film can not withstand and is destroyed by the voltage difference between the internal power supply voltage and the ground voltage.

In contrast, the semiconductor device 1 of the present embodiment includes, as shown in the circuit diagram of FIG. 5, the plurality of compensation capacitors 4 electrically coupled in series between the first power supply terminal 29 and the second power supply terminal 23. By doing this, the voltage difference applied to each of the compensation capacitors 4 is the voltage difference between the internal power supply voltage VOD and the ground voltage VSS divided by the number of compensation capacitors 4 electrically coupled in series. Compared to a compensation capacitor in the related art, therefore, the voltage difference applied to the compensation capacitors 4 in the present embodiment is small, enabling prevention of destruction of the capacitive insulating film 42.

To described this in more detail, if the ground voltage VSS is 0 V, the voltage difference between the internal power supply voltage VOD and the ground voltage VSS (0 V) is VOD, the potential of the upper electrode 43a is VOD, the potential of the lower electrodes 41a and 41b is ⅔×VOD, the potential of the upper electrodes 43b and 43c is ⅓×VOD, and the potential of the lower electrode 41c is 0 V. Therefore, the voltage difference applied to each of the compensation capacitors 4 is ⅓×VOD in all cases, this being a smaller voltage difference than in the related art, enabling prevention of destruction of the capacitive insulating film 42.

Also, in the semiconductor device 1 of the present embodiment, as shown in FIG. 3, because the shield wiring is provided that shields the connection wiring 22 or the second power supply terminal 23, it is possible to reduce the influence of noise on the upper electrode 43 or lower electrode 41.

The lower electrodes 41a and 41b and the upper electrodes 43b and 43c of the compensation capacitor 4 in the present embodiment are not directly electrically connected to the first power supply terminal 29 or the second power supply terminal 23. That is, the lower electrodes 41a and 41b and the upper electrodes 43b and 43c are electrically floated. Therefore, the electrical potential is not stable and there is a tendency for the electrical potential to fluctuate up and down because of noise.

However, in order to suppress the influence of noise, the shield wiring 5 is provided below the connection wirings 22a and 22b that connect the lower electrode 41a and lower electrode 41b in series. Also, the second power supply terminal 23, which functions as a shield wiring, is provided above the upper electrodes 43b and 43c. Because the shield wiring 5 and the second power supply terminal 23 are supplied with the ground voltage VSS, the electrical potential is fixed. Therefore, because a wiring having a fixed electrical potential exists nearby, the connection wiring 22 and the lower electrode 41 electrically connected thereto, and the upper electrode 43 each are at a stable electrical potential, thereby enabling the reduction of the influence of noise.

Also, although in the present embodiment there are three compensation capacitors 4 connected in series between the first power supply terminal 29 and the second power supply terminal 23, this number is not limited thereto. In consideration of the internal power supply voltage VOD and the withstand voltage and the like of the capacitive insulating film 42, the number may be made four or greater, or two.

Also, although the shield wiring 5 is electrically connected to the second power supply terminal 23, so that the shield wiring 5 is supplied with the ground voltage VSS, it is not absolutely necessary that the ground voltage VSS be supplied thereto. As long as there is not a large electrical potential fluctuation, such as on a signal wiring, the configuration may be one in which there is electrical connection to some other appropriate power supply wiring or the like. Also, although the second power supply terminal 23 is used as a shield wiring, a shield wiring separate from the second power supply terminal may be formed on the interlayer insulating film 35.

### <Method for Manufacturing a Semiconductor Device>

A method for forming the semiconductor device 1 of the present embodiment will be described in detail.

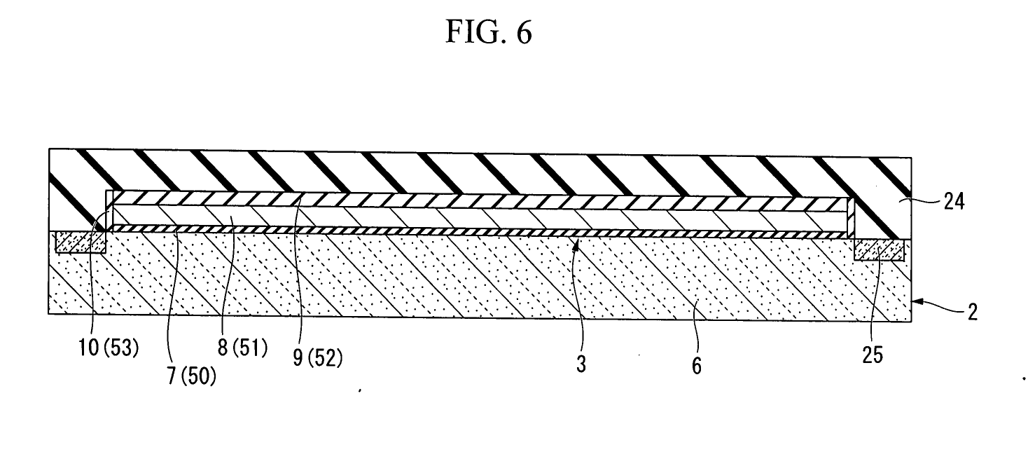

First, for example, as shown in FIG. 6, the n-type well region 6 is formed in the semiconductor substrate 2 made of p-type silicon.

Then, a gate insulating film material 50 is formed over the semiconductor substrate 2, and a gate electrode material 51 and a protective insulating film material 52 are laminated onto the gate electrode insulating film material 50 and patterned to form the gate insulating film 7, the gate electrode 8, and the protective insulating film 9.

Within the well region 6 of the semiconductor substrate 2, at a position that is self-aligning with respect to the protective insulating film 9, that is, at a position that is self-aligning with respect to the gate electrode 8, a p-type impurity is introduced to form the source and drain regions 25. The p-type impurity is such as, for example, boron (B).

The source and drain regions 25 are impurity diffusion regions. A side wall material 53 made of an insulating material is formed on the side surface of the gate electrode 8, and etching back is done to form side walls 10.

The transistor 3 is formed in the above-noted manner.

It is possible to use, for example, a silicon oxide film as the gate insulating film material 50. It is possible to use as the gate electrode material 51, a polycrystalline silicon film that includes, phosphorus, for example, or a tungsten (W) film, a tungsten silicide (WSi)) film or a laminate film made thereof.

Silicon nitride (Si₃N₄) film, for example, can be used as the protective insulating film material 52 and the side wall material 53.

After the formation of the transistor 3, a gate interlayer insulating film 24 is formed over the semiconductor substrate 2 so as to cover the gate electrode 8. The gate interlayer insulating film 24 is made of, for example, silicon oxide film or the like. The upper surface of the gate interlayer insulating film 24 is then polished using CMP and planarized.

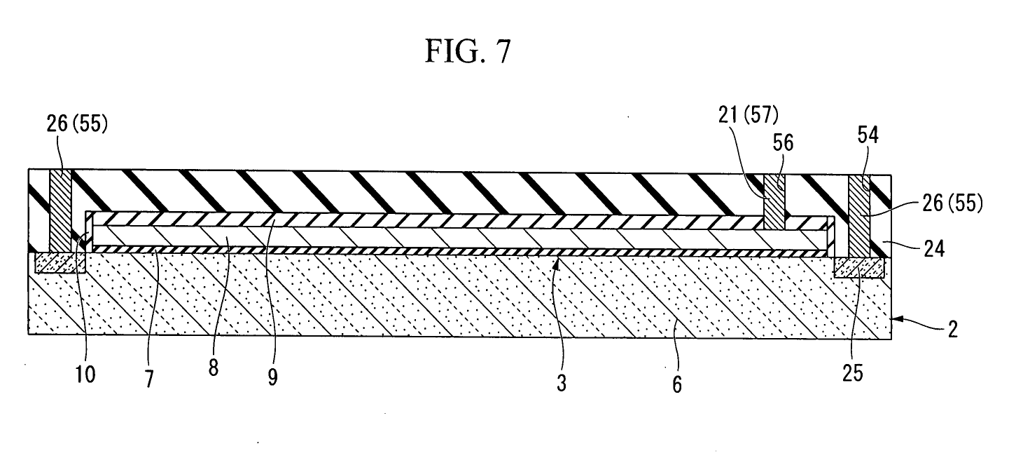

As shown in FIG. 7, contact holes 54 are formed so as to penetrate the gate interlayer insulating film 24, and a contact hole 56 is formed so as to penetrate the gate interlayer insulating film 24 and the protective insulating film 9.

A contact plug material 55 is filled into the contact holes 54 so as to form the contact plugs 26 that are electrically connected to the source and drain regions 25, respectively. A contact plug 57 is filled into the contact hole 56, so as to form the contact plug 21 that is electrically connected to the gate electrode 8.

For example, a polycrystalline silicon film that contains phosphorus, or a tungsten film or the like can be used as the contact plug materials 55 and 57.

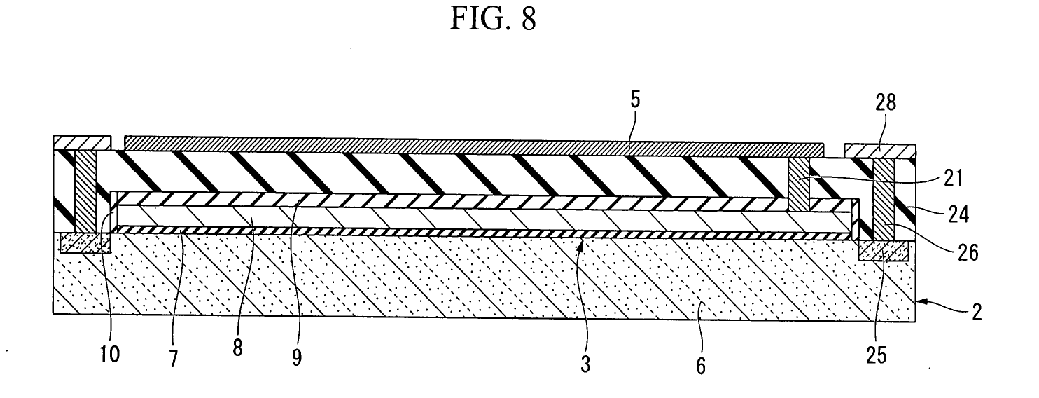

As shown in FIG. 8, the wirings 28 are formed on the contact plugs 26 so as to be electrically connected to the source and drain regions 25 over the gate interlayer insulating film 24, respectively. The material of the wirings 28 may be, but is not limited to, a laminate of tungsten nitride (WN) or tungsten (W).

The shield wiring 5 is formed on the gate interlayer insulating film 24, over substantially the entire region in which the compensation capacitor 4 is provided in subsequent process steps. The compensation capacitor 4 is formed above the region in which the shield wiring 5 is formed. The material of the shield wiring 5 may include, but is not limited to, a laminate of tungsten nitride (WN) or tungsten (W).

The shield wiring 5 is electrically connected to the gate electrode 8 via the contact plug 21.

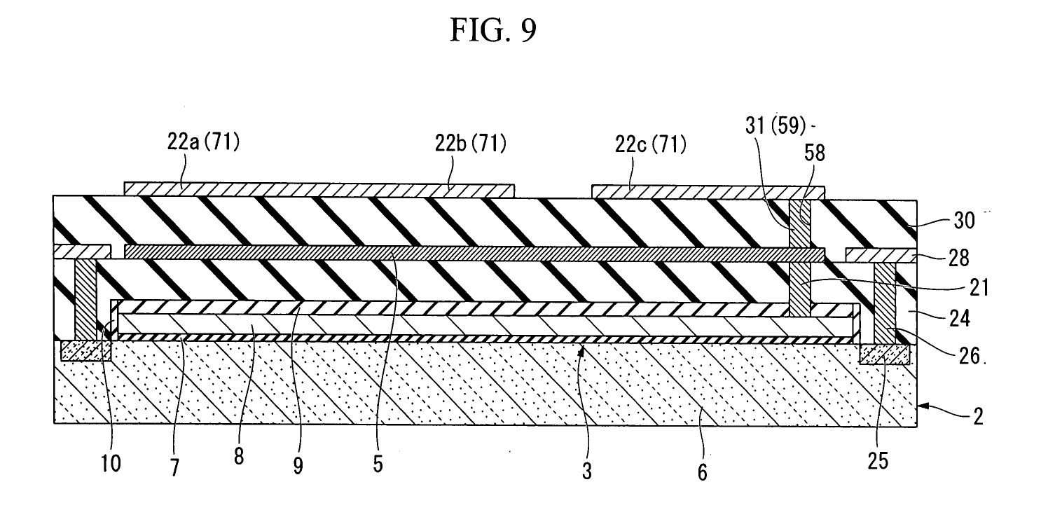

As shown in FIG. 9, the interlayer insulating film 30 including, for example, silicon oxide or the like is formed so as to cover the wiring 28 and the shield wiring 5. The upper surface of the interlayer insulating film 30 is then polished using CMP and planarized.

After the above, a contact hole 58 is formed so as to penetrate the interlayer insulating film 30. The contact hole 58 is then filled with a contact plug material 59, forming a contact plug 31. The contact plug 31 connects to the shield wiring 5. A tungsten film or the like may be used as the contact plug material 59.

A laminate 71 is formed on the interlayer insulating film 30 by successive deposition of, for example, a tungsten nitride (WN) film and a tungsten (W) film. The laminate 71 is patterned and the plurality of connection wirings 22 (22a, 22b and 22c) are formed. The connection wiring 22 is connected to the bottom surface of the lower electrodes 41 (41a, 41b, and 41c) of the compensation capacitors 4 (4a, 4b, and 4c) to be described later.

When the laminate 71 is patterned, the connection wiring 22a and the connection wiring 22b are formed as one so that the connection wiring 22a and the connection wiring 22b are electrically connected. The connection wiring 22a is connected to the lower electrode 41 a of the compensation capacitor 4a. The connection wiring 22b is connected to the lower electrode 41b of the compensation capacitor 4b. The connection wiring 22a and the connection wiring 22b, and the connection wiring 22c that is connected to the lower electrode 41c of the compensation capacitor 4c are formed so that they are electrically separated.

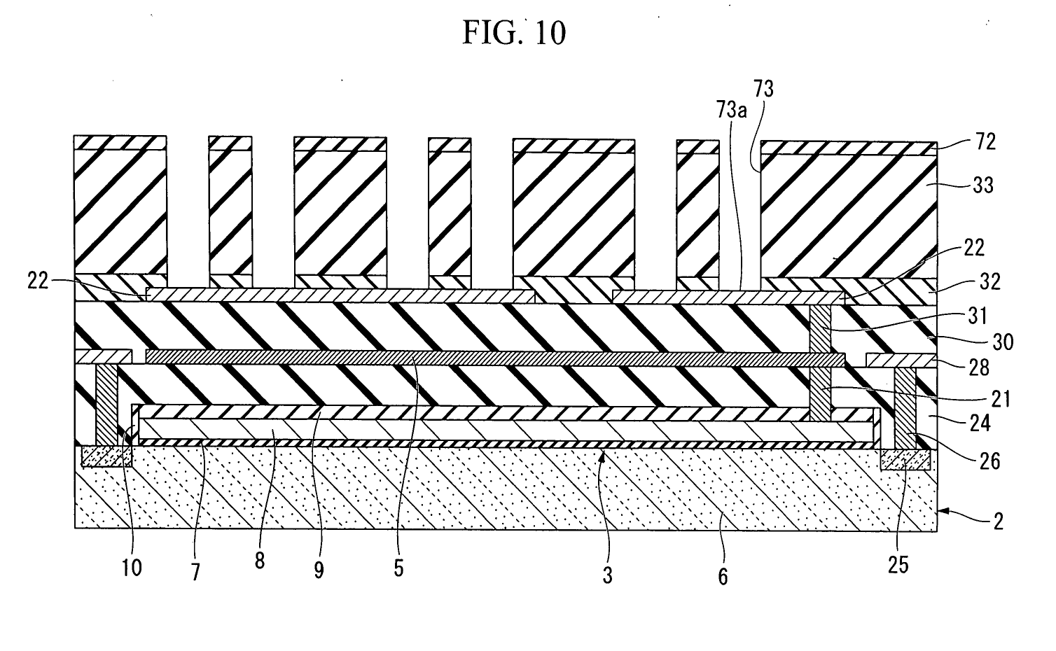

As shown in FIG. 10, a silicon nitride film with a thickness of, for example, approximately 40 nm to 100 nm is deposited using, for example, LP-CVD or ALD, so as to cover the connection wiring 22.

An interlayer insulating film 33 with a thickness of, for example, approximately 1 p.m to 2 p.m and a support film material 72 with a thickness of approximately 50 nm to 150 nm are successively deposited over the stopper film 32.

It is possible to use, but is not limited to, as the material for the interlayer insulating film 33, a silicon oxide film, a BPSG film that includes an impurity, or a laminate of such films. It is possible to use, but is not limited to, as the support film material 72 a silicon nitride film that is deposited using LP-CVD or ALD.

Anisotropic dry etching is performed to form an opening 73 so as to penetrate the support film material 72, the interlayer insulating film 33, and the stopper film 32. When doing this, the upper surface of the connection wiring 22 is allowed to be shown at the bottom part 73a through the opening 73.

The position of the opening 73 establishes the number and positions of the lower electrodes 41 of the compensation capacitor 4 to be described later.

The height of the compensation capacitor 4 is established by the film thickness of the interlayer insulating film 33, and this is reflected in the electrostatic capacitance thereof. Although the thicker the interlayer insulating film 33 is made, the greater will be the electrostatic capacitance, because of the difficulty in processing the opening 73, it is preferable that the film thickness be set so that the aspect ratio (ratio of the column height to the diameter) of the opening 73 is approximately 15 to 25.

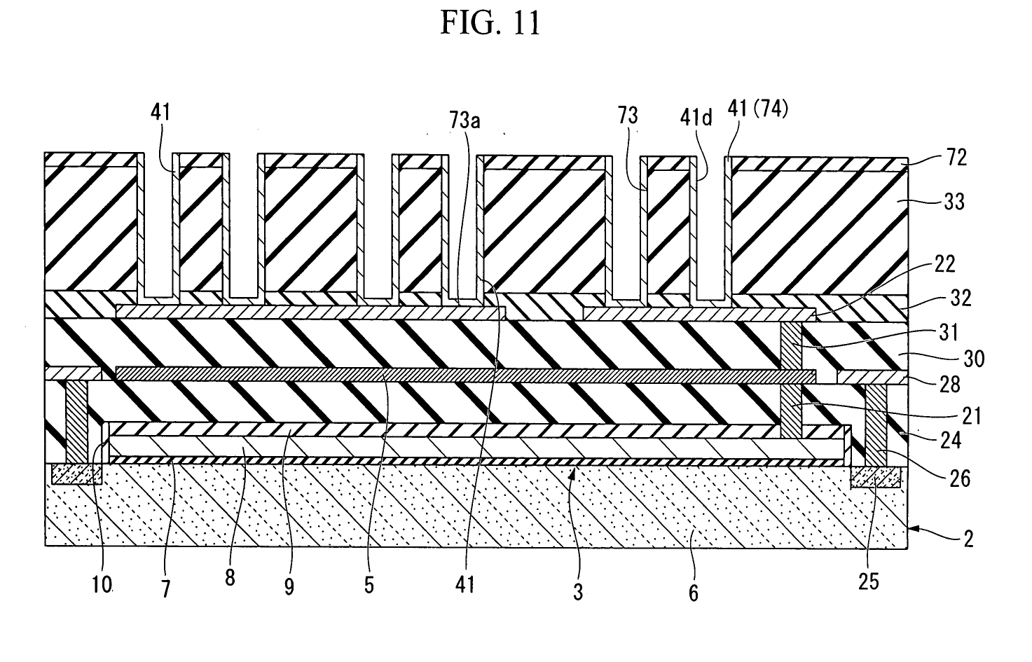

As shown in FIG. 11, a metal film is deposited by CVD to form a lower electrode film 74 on the support film material 72 and within the opening 73. Titanium nitride (TiN), for example, can be used as a material for the lower electrode film 74. When doing this, the lower electrode film 74 is formed with a film thickness that does not fill the inside of the opening 73. For example, in the case in which the diameter of the opening 73 is 80 nm, the thickness of the lower electrode film 74 is formed to be approximately 10 nm to 20 nm.

Dry etching is performed to remove the lower electrode film 74 positioned outside the opening 73. When this is done, in the case in which the aspect ratio of the opening 73 is high (15 or greater), it is possible to remove the lower electrode film 74 over the support film material 72 without damages of the lower electrode film 74 that covers over the bottom part 73a of the opening 73.

By doing the above, the lower electrode 41 is formed to cover the inner wall of the aperture 73. The lower electrode 41 has the shape of a bottomed cylinder. The inner wall surface 48 of the lower electrode is exposed.

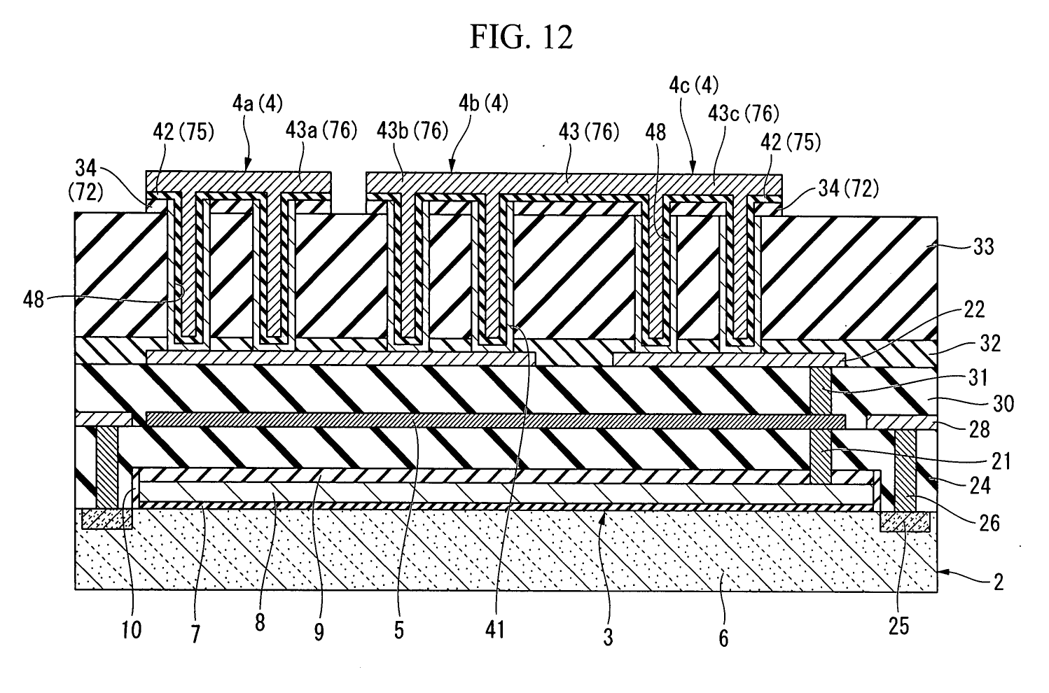

As shown in FIG. 12, a capacitive insulating film material 75 is formed with a thickness of, for example, approximately 6 nm to 10 nm, so as to cover the support film material 72 and the exposed inside wall surface 48 of the lower electrode 41. It is possible to use a high dielectric material such as zirconium oxide (ZrO₂), hafnium oxide (HfO₂), and aluminum oxide (Al₂O₃) or the like, or a laminate thereof as the capacitive insulating film material 75, but is not limited thereto. The capacitive insulating film material 75 can be formed using, for example, ALD.

The capacitive insulating film material 75 is formed so that the inside of the lower electrode 41 is not filled.

After forming the capacitive insulating film material 75, an upper electrode film 76 is formed so as to cover the surface of the capacitive insulating film material 75. Titanium nitride (TiN) or the like, for example, can be used as the upper electrode film 76. The upper electrode film 76 may have a laminated conductor structure. It may be a laminated film in which, after depositing a titanium nitride film or the like with a thickness of 8 nm to 10 nm, a polycrystalline silicon film containing an impurity such as boron and a tungsten film are successively deposited.

The upper electrode film 76 is formed so that the inside of the lower electrode 41 is filled while the capacitive insulating film material 75 is interposed between the upper electrode film 76 and the lower electrode 41.

The upper electrode film 76 and the capacitive insulating film material 75 are patterned. The plurality of upper electrodes 43 and the capacitive insulating films 42 are formed. When this is done, it is preferable to simultaneously pattern the support film material 72 and to form the support film 34. By patterning the support film material 72 as well, subsequent process steps of forming the contact plugs 45, 46, and 27 and the like are facilitated.

When patterning the upper electrode film 76, the capacitive insulating film material 75, and the support film material 72, the upper electrode 43b of the compensation capacitor 4b and the upper electrode 43c of the compensation capacitor 4c are formed as one so that they are electrically connected. The upper electrode 43b and the upper electrode 43c, and the compensating capacitive upper electrode 43a of the compensation capacitor 4a are formed so that they are electrically separated.

By dong the above, the compensation capacitor 4 formed by the plurality of lower electrodes 41, the capacitive insulating film 42, and the upper electrode 43 is formed.

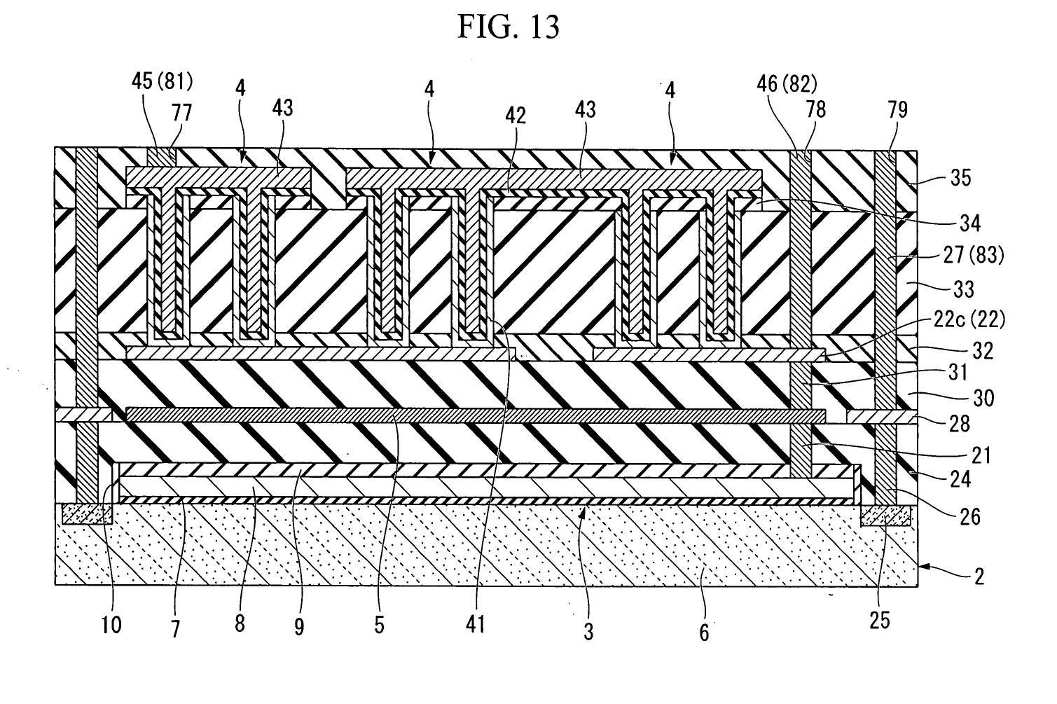

As shown in FIG. 13, the interlayer insulating film 35 is formed using, for example, silicon oxide, so as to cover the upper electrode 43. The upper surface of the interlayer insulating film 35 is polished using CMP and planarized.

A contact hole 77 that penetrates the interlayer insulating film 35 is formed. A contact hole 78 that penetrates the interlayer insulating films 35 and 33 and the stopper film 32 is formed. A contact hole 79 that passes through the interlayer insulating films 35, 33, and 30 and the stopper film 32 is formed.

By filling the contact hole 77 with the contact plug material 81, the contact plug 45 connecting to the upper electrode 43 is formed. By filling the contact hole 78 with the contact plug material 82, the contact plug 46 connecting to the connection wiring 22c is formed. By filling the contact hole 79 with the contact plug material 83, the contact plug 27 connecting to the wiring 28 is formed.

A polycrystalline silicon film containing, for example, phosphorus, or a tungsten film or the like can be used as the contact plug materials 81, 82, and 83.

After the above, the first power supply terminals 29 that connect to the contact plugs 27 and the contact plug 45, and a second power supply terminal 23 that connects to the contact plug 46 are formed on the interlayer insulating film 35 using, for example, aluminum (Al) or copper (Cu) or the like.

A protective film for protecting the surface of the semiconductor device (no illustrated) or the like is formed on the surface. Then, the semiconductor device 1 shown in FIG. 3 is completed.

### SECOND EMBODIMENT

### <Semiconductor Device>

According to a second embodiment, a semiconductor device 91 will be described. The present embodiment is a variation of the first embodiment, and is different from the first embodiment with respect to the constitution of the shield wiring, the description of other, similar parts thereof being omitted herein.

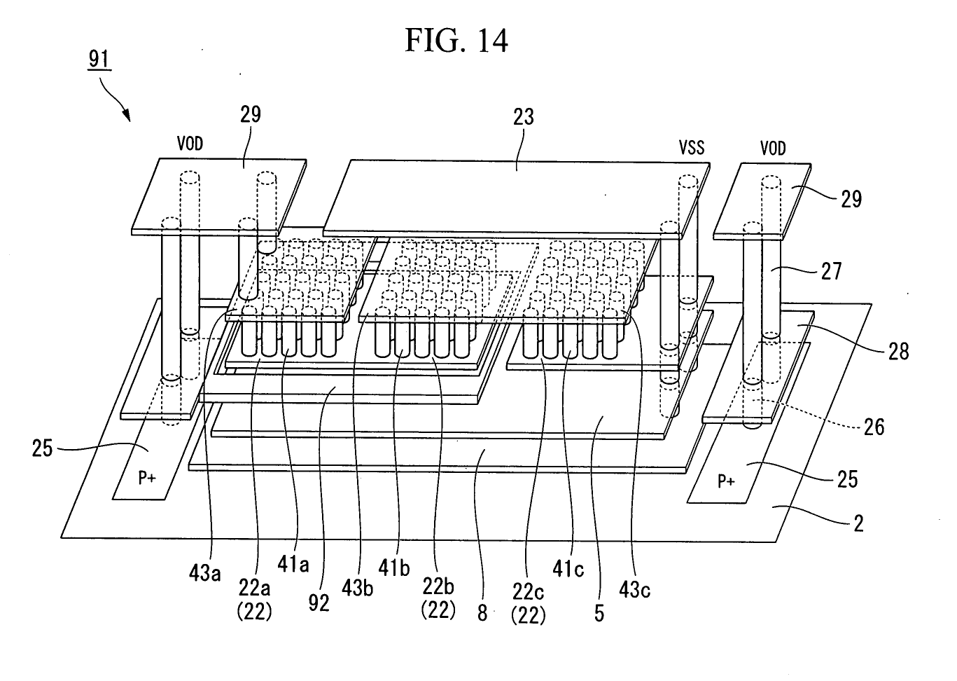

The semiconductor device 91 of the present embodiment differs from the first embodiment, as shown in FIG. 14, in that it is provided with an outer peripheral shield wiring 92 functioning as the shield wiring, with other elements of the constitution thereof being the same as in the first embodiment. FIG. 14 is a fragmentary perspective view illustrating a semiconductor device in accordance with another embodiment of the present invention.

Specifically, the outer peripheral shield wiring 92 is provided at a position that is substantially at the same height as the connection wiring 22 from the semiconductor substrate 2. The outer peripheral shield wiring 92 is formed so as to connect to the second power supply terminal 23 via a contact plug or the like that is not illustrated.

The outer peripheral shield wiring 92 is formed so as to connect the compensation capacitor 4a and the compensation capacitor 4b in series. The outer peripheral shield wiring 92 is formed so as to surround the outer periphery of the connection wirings 22a and 22b which have a fixed electrical potential.

In this case, the outer peripheral shield wiring 92 is formed so as to not connect the connection wirings 22a and 22b directly. In order to cause it to function as a shield, it is preferable that it has a small distance between the outer peripheral shield wiring 92 and the connection wirings 22a and 22b.

The semiconductor device 91 according to the present embodiment, similar to the first embodiment, also has a plurality of compensation capacitors 4 connected in series between the first power supply terminal 29 and the second power supply terminal 23. The first power supply terminal 29 is supplied with the internal power supply voltage VOD. The second power supply terminal 23 is supplied with the ground voltage VSS. By doing this, it is possible to prevent the destruction of the capacitive insulating films 42 of each of the compensation capacitors 4.

Because the shield wiring 5 and the second power supply terminal 23 function as shield wirings, the electrical potential of the lower electrode 41 and the upper electrode 43 is stabilized, and it is possible to suppress the influence of noise.

In the present embodiment, the outer peripheral shield wiring 92, to which the ground voltage VSS is supplied, is provided on the outer periphery of the connection wirings 22a and 22b. In comparison with the first embodiment, the electrical potential of the connection wirings 22a and 22b is more stable, enabling the reduction of the influence of noise at the lower electrode 41.

Also, according to the present embodiment, the outer peripheral shield wiring 92 is electrically connected to the second power supply terminal 23 so that it is supplied with the ground voltage VSS. However, there is no absolute need for it to be supplied with the ground voltage VSS. As long as it is not a wiring having a large electrical potential fluctuation, such as a signal wiring, the configuration may be one in which there is electrical connection to some other appropriate power supply wiring or the like.

If a sufficient shielding effect is achieved by the outer peripheral shield wiring 92, the shield wiring 5 may be omitted.

The outer peripheral shield wiring 92 may be formed so as to surround not the connection wirings 22a and 22b, but rather to surround the outer periphery of the upper electrodes 43b and 43c. The upper electrodes 43b and 43c function as wirings to connect the compensation capacitors 4b and 4c in series and have an unstable electrical potential. It is also possible to use two, one that surrounds the outer periphery of the connection wirings 22a and 22b, and the other that surrounds the outer periphery of the upper electrodes 43a and 43b. In the case of surrounding the outer periphery of the upper electrodes 43b and 43c, the outer peripheral shield wiring 92 can be provided at a position that is substantially at the same height from the semiconductor substrate 2 as the upper electrode 43. The upper electrode 43 is formed further above the upper end of the lower electrode 41. That is, a wiring layer can be formed above the capacitive insulating film 42 over the support film 34.

By providing the outer peripheral shield wiring 92 that surrounds the outer periphery of the upper electrodes 43b and 43c in this manner, compared with the first embodiment, the electrical potential of the upper electrode 43 is more stable, enabling suppression of the influence of noise.

### <Method for Manufacturing a Semiconductor Device>

A method for forming the semiconductor device of the present embodiment will be described. The semiconductor device 91 of the present embodiment can be formed substantially in the same manner as in the first embodiment, with the exception of the process step for forming the outer peripheral shield wiring 92.

The outer peripheral shield wiring 92 may be formed on the interlayer insulating film 30 so as to surround the outer periphery of at least the connection wirings 22a and 22b while the connection wirings 22 are formed as in the first embodiment (refer to FIG. 9).

More specifically, in the first embodiment, the laminate 71 that is the successive deposition of, for example, the tungsten nitride (WN) film and the tungsten (W) film is patterned and the connection wiring 22 is formed.

In contrast, in this embodiment, in addition to forming the connection wiring 22, the laminate 71 can be patterned so that the outer peripheral shield wiring 92 surrounds the outer periphery of the connection wirings 22a and 22b, without making a direct connection to the connection wirings 22a and 22b.

By performing the other process steps, which are the same as in the first embodiment, the semiconductor device 91 is completed.

### THIRD EMBODIMENT

### <Semiconductor Device>

A semiconductor device 101 according to the third embodiment will be described. The present embodiment is a variation of the first embodiment, and is different from the first embodiment with respect to the constitution of the shield wiring, the description of other, similar parts thereof being omitted herein.

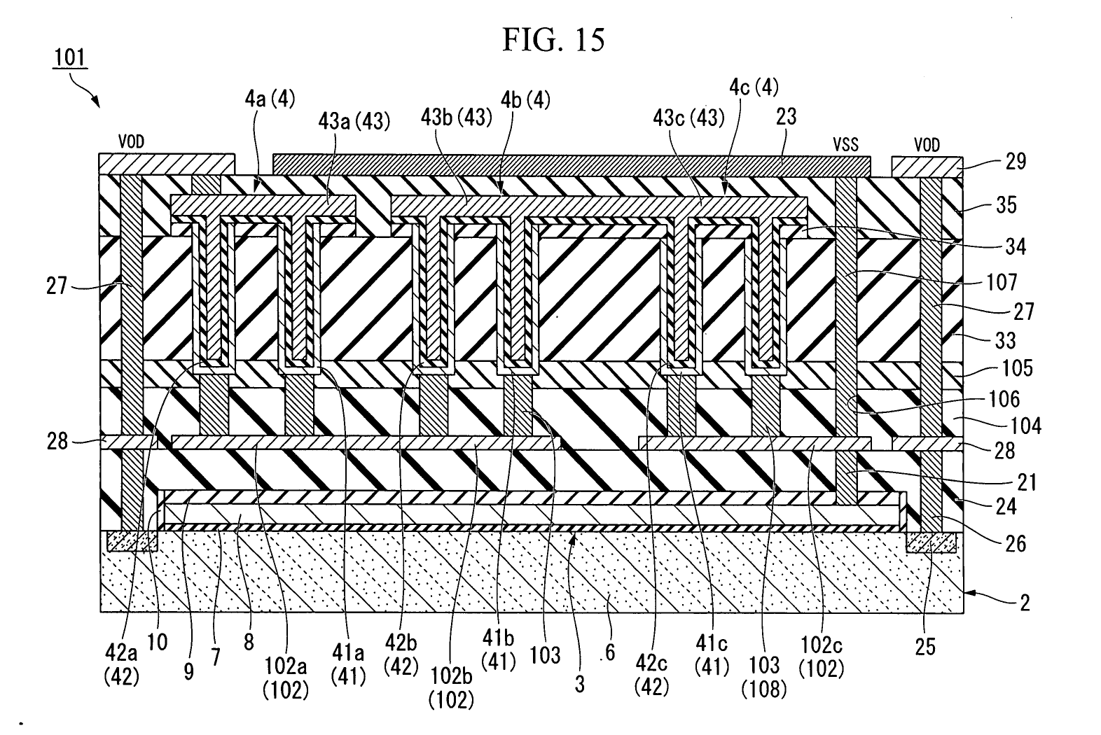

In the semiconductor device 101, as shown in FIG. 15, the lower shield wiring is not provided. Wirings 102 (102a, 102b, and 102c) are provided on the gate interlayer insulating film 24. In the present embodiment, because the gate electrode 8 functions as the shield wiring, it is preferable that the distance between the wiring 102 and gate electrode 8 is small.

The gate electrode 8 is formed over substantially the entire region in which the compensation capacitor 4 is provided. The gate electrode 8 is electrically connected to the second power supply terminal 23, via the contact plug 21, a contact plug 107 and the wiring 102c.

The wiring 102 are formed as one so that the wiring 102a and the wiring 102b are electrically connected, similar to the connection wirings 22 of the first embodiment. The wiring 102c is formed so as to be insulated and separated from the wirings 102a and 102b.

A contact plug 103 is formed on the wiring 102, and is electrically connected to the lower electrode 41 of the compensation capacitor 4 via the contact plug 103.

Specifically, an interlayer insulating film 104 is provided over the wiring 102, and a stopper film 105 is formed on the interlayer insulating film 104.

The contact plug 103 penetrates the interlayer insulating film 104 and the stopper film 105 so as to electrically connect to the wiring 102. The upper end of the contact plug 103 is formed nearer the semiconductor substrate 2 than the upper surface of the stopper film 105.

The lower electrode 41 of the compensation capacitor 4 is formed so that the bottom surface thereof is connected to the contact plug 103. That is, the lower electrodes 41a, 41b, and 41c are connected to the wirings 102a, 102b and 102c, respectively, via the contact plug 103.

The other parts of the constitution are the same as the first embodiment.

The semiconductor device 101 of the present embodiment, similar to the first embodiment, also has a plurality of compensation capacitors 4 connected in series between the first power supply terminal 29 and the second power supply terminal 23. The first power supply terminal 29 is supplied with the internal power supply voltage VOD. The second power supply terminal 23 is supplied with the ground voltage VSS. By doing this, it is possible to prevent the destruction of the capacitive insulating films 42 of each of the compensation capacitors 4.

Although the present embodiment does not have the lower shield wiring, the distance between the wirings 102a and 102b and the gate electrode 8 in which the ground voltage VSS is supplied is formed to be small. The wirings 102a and 102b connect the compensation capacitors 4a and 4b in series. The wirings 102a and 102b have an unstable electrical potential. By doing this, the gate electrode 8 functions as a shield wiring, so that the electrical potential of the wirings 102a and 102b is stabilized and, as a results of this, the electrical potential of the lower electrodes 41a and 41b is stabilized. It is possible to reduce the influence of noise at the lower electrode 41. Because the second power supply terminal 23 functions as the shield wiring, similar to the first embodiment, it is possible to reduce the influence of noise on the upper electrode 43.

### <Method for Manufacturing a Semiconductor Device>

A method for manufacturing the semiconductor device 101 of the present embodiment will be described. The semiconductor device 101 of the present embodiment can be manufactured substantially the same as the first embodiment, and the descriptions of similar parts thereof are omitted herein.

Similar to the first embodiment, as shown in FIG. 7, after forming the transistor 3, the gate interlayer insulating film 24 is formed on the semiconductor substrate 2, and the contact plugs 21 and 26 are formed.

After that, although in the first embodiment the wiring 28 and the shield wiring 5 are formed on the gate interlayer insulating film 24, in the case of the present embodiment, the wiring 102 is formed in addition to the wiring 28.

Specifically, a laminate is formed on the gate interlayer insulating film by successive deposition of, for example, a tungsten nitride (WN) film and a tungsten (W) film, and patterning thereof, so as to form the wirings 28 and 102.

When doing this, the patterning is performed so that the wirings 102a and 102b are formed as one so as to be electrically connected, and the patterning is performed so that the wiring 102c is insulated and separated from the wirings 102a and 102b.

The interlayer insulating film 104 is formed on the gate interlayer insulating film 24 so as to cover the wiring 102, and the stopper film 105 is then formed on the interlayer insulating film 104.

After the above, a contact hole 106 that penetrates the stopper film 105 and the interlayer insulating film 104 is formed by filling the contact hole 106 with the contact plug material 108, thereby forming the contact plug 103 that is electrically connected to the wiring 102. When doing this, the upper end of the contact plug 103 is formed nearer the semiconductor substrate 2 than the upper surface of the stopper film 105.

Then, similar to the first embodiment, the interlayer insulating film 33 and the support film material 74 are successively formed. The opening 73 is formed so that the upper end of the contact plug 103 is opened. The lower electrode 41 is formed within the opening 73. After that, the semiconductor device 101 is completed in the same manner as in the first embodiment.

### FOURTH EMBODIMENT

### <Semiconductor Device>

A semiconductor device 111, which is the fourth embodiment of the present invention, will be described. The present embodiment is a variation of the first embodiment, the description of similar parts thereof being omitted herein.

The compensation capacitor having a concave capacitive element is used in the first embodiment. According to the present embodiment, a compensation capacitor has a so-called crown-type capacitor element. The crown-type capacitor element has an electrode structure using both an inner wall surface and an outer surface of the lower electrode formed as a cup shape is used as the capacitor electrode.

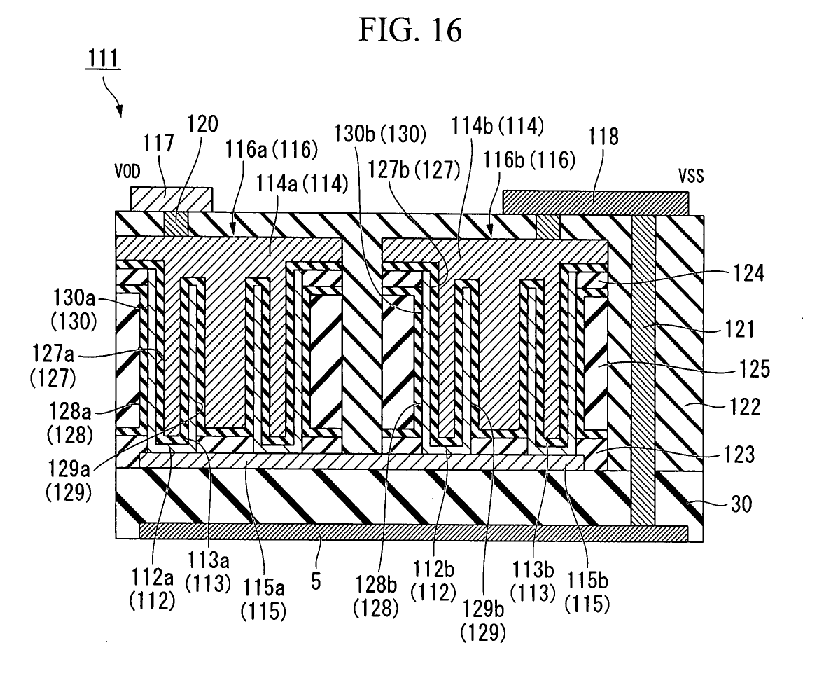

As shown in the FIG. 16, compensation capacitors 116 (116a and 116b) of the semiconductor device 111 may include, but is not limited to, a plurality of bottomed cylindrically shaped lower electrodes 112 (112a and 112b), capacitive insulating films 113 (113a and 113b), and upper electrodes 114 (114a and 114b). The capacitive insulating films 113 (113a and 113b) cover inner surfaces 127 (127a and 127b) and outer surfaces 128 (128a and 128b) of the lower electrode 112. The upper electrodes 114 (114a and 114b) are provided on the capacitive insulating film 113.

FIG. 16 is a fragmentary cross sectional elevation view illustrating a semiconductor device in accordance with yet another embodiment of the present invention. Because a layer part that is lower than the interlayer insulating film 30 of the semiconductor device 111 has a structure similar to that of the first embodiment, the description thereof is omitted herein.

The inner wall surface 127 of the lower electrode 112 of the compensation capacitor 116 is covered by the capacitive insulating film 113. Outer wall surfaces 129 (129a and 129b) are first parts of the outer wall surfaces 128 of the lower electrodes 112a and 112b. The outer wall surfaces 129 are opposite to the outer wall surface 128 of the other lower electrode 112 of the same compensation capacitor 116. The outer wall surfaces 129 are covered by the capacitive insulating film 113. Outer wall surfaces 130 (130a and 130b) are second parts of the outer wall surfaces 128 of the lower electrode 112a and 112b. The outer wall surfaces 130 are not opposite to the outer wall surface 128 of the other lower electrode 112 of the same compensation capacitor 116. The outer wall surfaces 130 are covered by the stopper film 123, the interlayer insulating film 125, and the support film 124.

For example, the compensation capacitor 116a includes a plurality of the lower electrodes 112a. The outer wall surface 130a is the second part of the outer wall surface 128a of the lower electrode 112a which is disposed on the outermost periphery of the compensation capacitor 116a. The only the outer wall surface 130a disposed at the outermost of the compensation capacitor 116a is covered by the stopper film 23, the interlayer insulating film 125, and the support film 124.

In contrast, the outer wall surface 128a (129a) of the lower electrode 112a which is not disposed on the outermost periphery is covered by the capacitive insulating film 113. Also, the outer wall surface 129a of the lower electrode 112a which is disposed on the outermost periphery, which is opposed to the outer wall surface 128a of the other lower electrode 112a of the compensation capacitor 116a, is covered by the capacitive insulating film 113.

The capacitive insulating film 113 covers as one the plurality of lower electrodes 112 without filling the inside of the lower electrode 112 and between the lower electrodes 112.

The upper electrode 114 is provided on the capacitive insulating film 113. The upper electrode 114 fills the inside of the lower electrode 112 and between the lower electrodes 112 via the capacitive insulating film 113. The upper electrode 114, similar to the capacitive insulating film 113, covers as one the plurality of lower electrodes 112 of the compensation capacitor 116 while the capacitive insulating film 113 is interposed between the upper electrode 114 and the lower electrodes 112.

The bottom surfaces of the plurality of lower electrodes 112 of the compensation capacitor 113 are in contact the wirings 115 (115a and 115b), respectively. The lower electrodes 112 of the compensation capacitors 116 are electrically connected to each other by the wiring 115. The wirings 115a and 115b are formed as one and are electrically connected to each other.

An interlayer insulating film 122 is provided above the interlayer insulating film 30, so as to cover a compensation capacitor 116. Above the interlayer insulating film 122, the first power supply terminal 117, to which the internal power supply voltage VOD is supplied, and the second power supply terminal 118, to which the ground voltage VSS is supplied, are provided.

The second power supply terminal 118, in contrast to the first embodiment, rather than being formed over the entire region in which a plurality of the compensation capacitor 116 is provided, is only formed so as to cover a part of the region in which the compensation capacitor 116b is provided.

The first power supply terminal 117 is electrically connected to the upper electrode 114a of the compensation capacitor 116a, via the contact plug 120.

The second power supply terminal 118 is electrically connected to the upper electrode 114b of the compensation capacitor 116b, via the contact plug 129. The second power supply terminal 118 is also electrically connected to the shield wiring 5, via the contact plug 121.

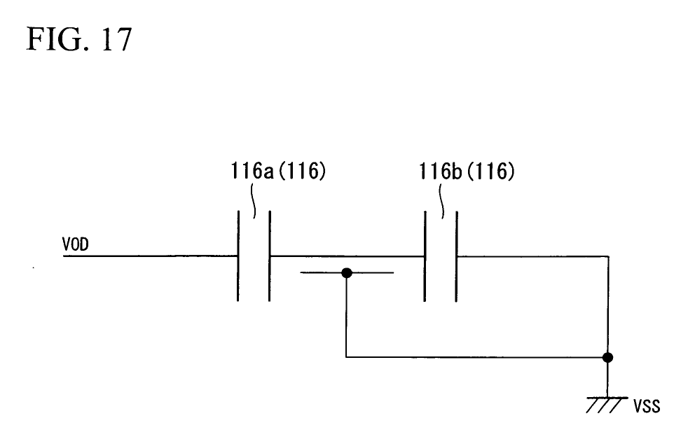

The semiconductor device 111 according to the present embodiment, similar to the first embodiment, as shown in the circuit diagram of FIG. 17, may include, but is not limited to, two compensation capacitors 116 which are connected in series between the first power supply terminal 117 and the second power supply terminal 118. The internal power supply voltage VOD is supplied to the first power supply terminal 117. The ground voltage VSS is supplied to the second power supply terminal 118.

By doing this, it is possible to prevent the destruction of the capacitive insulating film 113 of each of the compensation capacitors 116.

According to the present embodiment, because the compensation capacitor 116 is formed with the crown-type electrode structure, it is possible to make the capacitance per unit surface area larger than that of the first embodiment, thereby enabling miniaturization of the compensation capacitor 116.

According to the present embodiment, because the first power supply terminal 117 and the second power supply terminal 118 are electrically connected to the upper electrodes 114a and 114b, respectively, the electrical potentials of the first power supply terminal 117 and the second power supply terminal 118 is stable. Therefore, it is not necessary that the second power supply terminal 118 is made to function as a shield wiring. The compensation capacitors 116a and 116b are connected in series via the lower electrode 112 whose electrical potential is unstable similar to the first embodiment. Since the lower electrode 112 is shielded by the shield wiring 5, it is possible to suppress the influence of noise on the lower electrode 112.

Although the present embodiment is described for the case in which two compensation capacitors 116 are connected in series, it is not absolutely necessary to have two, and the number may be three or greater.

Although it may be possible to form the upper electrode with unstable electrical potential using three or more compensation capacitors, in this case, similar to the first embodiment, it is preferable that the second power supply terminal 118 is formed over substantially the entire region in which the compensation capacitors are formed.

### <Method for Manufacturing a Semiconductor Device>

A method for forming the semiconductor device of the present embodiment will be described. The semiconductor device 111 according to the present embodiment can be formed substantially in the same manner as in the first embodiment, with the exception of the process step for exposing the outer wall surface 128 of the lower electrode 112.

As the method for exposing the outer wall surface 128 of the lower electrode 112, it may be possible to use a widely known method for forming a crown-type capacitor. For example, similar to the first embodiment, the lower electrode film 74 is formed in the opening 73 (refer to FIG. 11). Then, wet etching process may be performed to remove the interlayer insulating film 33 which covers the outer wall surface 129 to be exposed, for example, using diluted hydrofluoric acid as the chemical.

As shown in FIG. 16, because the stopper film 123 inhibits the permeation of the chemical, it is possible to prevent the unnecessary etching of the interlayer insulating film 33. By performing the other process steps, which are the same as in the first embodiment, the semiconductor device 111 according to the present embodiment is completed.

In the present embodiment, for example, although the compensation capacitor 4 and 116 have substantially the same constitution as a cell capacitor, but is not limited thereto. If an insulating film is provided between the electrode of the upper layer and the electrode of the lower layer, the present embodiment is applicable. The shield wirings which shield the upper electrode and the lower electrode, respectively, may be provided. However, even if only a shield wiring which shields one of the upper electrode and the lower electrode is provided, the effect of the present embodiment of suppressing the influence of noise on the upper electrode or the lower electrode can be achieved.

The present embodiment relates to a semiconductor device and can be widely used in the manufacturing industry in the manufacture of semiconductor devices.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The term “configured” is used to describe a component, section or part of a device includes hardware that is constructed to carry out the desired function.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a first power supply terminal configured to be supplied with a first electrical potential;
a second power supply terminal configured to be supplied with a second electrical potential, the second electrical potential being different from the first electrical potential; and
first and second capacitors being coupled in series between the first and second power supply terminals.

2. The semiconductor device according to claim 1, further comprising:
a connection wiring coupling the first and second capacitors.

3. The semiconductor device according to claim 2, further comprising:
a shield wiring overlapping an entire region of the connection wiring.

4. The semiconductor device according to claim 2, wherein the first capacitor comprises first and second electrodes,
the second capacitor comprises third and fourth electrodes, the third electrode being coupled to the first electrode via the connection wiring.

5. The semiconductor device according to claim 4, wherein the first and third electrodes are electrically floated.

6. The semiconductor device according to claim 4, wherein the second electrode is configured to be supplied with the first electrical potential.

7. The semiconductor device according to claim 4, further comprising:
a third capacitor coupled to the second capacitor in series, the third capacitor comprising fifth and sixth electrodes, the fifth electrode being coupled to the fourth electrodes.

8. The semiconductor device according to claim 7, wherein the fourth and fifth electrodes are electrically floated.

9. The semiconductor device according to claim 8, the second power supply line overlaps the entire regions of the fourth and fifth electrodes.

10. The semiconductor device according to claim 3, further comprising:
a transistor coupled to the first and second capacitors, the shielding wiring overlapping the transistor.

11. A semiconductor device comprising:
a shielding wiring;
a connection wiring adjacent to and separated from the shielding wiring;
a first power supply terminal;
first and second capacitors being coupled in series to the power supply terminal, the first and second capacitors being coupled via the connection wirings to each other; and
a transistor coupled to one of the first and second capacitors, the shield wiring being disposed between the transistor and a combination of the first and second capacitors.

12. The semiconductor device according to claim 11, wherein the shield wiring is supplied with substantially the same potential as the first power supply terminal.

13. The semiconductor device according to claim 11, wherein the connection wiring is supplied with substantially the same potential as the first power supply terminal.

14. The semiconductor device according to claim 11, wherein the connection wiring is disposed over the shielding wiring.

15. The semiconductor device according to claim 11, further comprising:
a second power supply terminal, the first and second capacitors being coupled in series between the first and second power supply terminals.

16. A semiconductor device comprising:
a multilevel wiring structure including first, second and third levels of wiring, the second level of wiring being between the first and third levels of wiring;
a first wiring layer formed as one of the first and third levels of wiring, the first wiring layer being electrically fixed; and
a capacitive structure including first and second capacitors connected in series and each including first and second electrodes, a second wiring layer formed as the second level of wiring to serve in common as the first electrodes of the first and second capacitors, a third wiring layer formed as the other of the first and third levels of wiring layer to serve as the second electrode of the first capacitor, and a fourth wiring layer formed as the other of the first and third levels of wiring to serve as the second electrode of the second capacitor,
wherein the first wiring layer being provided adjacently to the second wiring layer.

17. The semiconductor device according to claim 16, wherein the capacitive structure further comprises:
a third capacitor, which includes first and second electrodes, connected in series to the first and second capacitors; and
a fifth wiring layer formed as the second level of wiring to serve as the first electrode of the third capacitor,
wherein the fourth wiring layer further serves as the second electrode of the third capacitor.

18. The semiconductor device according to claim 16, wherein the third wiring layer is electrically fixed and the second wiring layer is electrically floated.

19. The semiconductor device according to claim 17, wherein the multilevel wiring structure further includes a fourth level of wiring adjacent to the third level of wiring,
wherein the semiconductor device further comprises:
a sixth wiring layer as the fourth level of wiring, the sixth wiring layer being electrically fixed, and the sixth wiring layer being provided adjacently to the fourth wiring layer.

20. The semiconductor device according to claim 19, wherein each of the third and fifth wiring layers is electrically fixed and each of the second and fourth wiring layers is electrically floated.
